(19) United States
(12) Patent Application Publication
(10) Pub. No.: US 2011/0199224 A1
(43) Pub. Date: Aug. 18, 2011

(54) SUBSTRATE INTER-TERMINAL VOLTAGE SENSING CIRCUIT

(75) Inventor: Tomohiko TATSUMI, Hyogo (JP)

(73) Assignee: OKI SEMICONDUCTOR CO., LTD., Tokyo (JP)

(21) Appl. No.: 13/029,417

(22) Filed: Feb. 17, 2011

(30) Foreign Application Priority Data
Feb. 18, 2010 (JP) 2010-033907
Feb. 3, 2011 (JP) 2011-021792

(51) Int. Cl. G08B 21/00; G01R 27/08

(52) U.S. Cl. 340/638; 324/713

(57) ABSTRACT

A substrate inter-terminal voltage sensing circuit which can promptly sense a plasma charge-up occurring on a semiconductor wafer across a wide range without connection of a voltage measuring instrument. The substrate inter-terminal voltage sensing circuit is adapted to sense a voltage occurring between a pair of electrodes arranged on a semiconductor substrate. The voltage sensing circuit includes a resistance path that is connected between the electrodes. The voltage sensing circuit also includes a circuit power supply that is connected at one end to a midpoint of the resistance path. The voltage sensing circuit also includes at least two fuse circuits that are connected between one end of the resistance path and the other end of the circuit power supply so as to be in parallel with each other. The fuse circuits have different rated fusing currents from each other. Each of the fuse circuits includes a switch that turns ON or OFF depending on a potential difference between the one end and midpoint of the resistance path. Each fuse circuit also has a current path that is connected across the circuit power supply. The current path possesses a resistive element and a fuse element serially connected to the switch.

### BACKGROUND OF THE INVENTION

The present invention relates to a circuit arrangement that senses electric charges occurring on a semiconductor substrate due to charged particles of plasma, and more particularly to a substrate inter-terminal voltage sensing circuit arrangement that can promptly measure a voltage corresponding to the amount of charges in a wireless manner without connection of a voltmeter.

### SUMMARY OF THE INVENTION

In the process of manufacturing semiconductor devices, plasma etching processing is used to form a hole pattern, well structure pattern and the like in a semiconductor wafer or an insulating film formed on the wafer. In the plasma etching process, the semiconductor wafer is irradiated with charged particles of plasma through a mask so as to form a certain pattern in or on the semiconductor wafer. Nonuniformity of the plasma produces uneven flows of charged particles into the wafer. This can cause a “charging” phenomenon on the semiconductor wafer when combined with the low electrical conductivities of the semiconductor wafer and the insulating film formed on the wafer. That is, the localization of positive or negative charges may result in the vicinity of the surface of the semiconductor wafer or the insulating film.

Plasma etching processing with such a “charging” phenomenon gives rise to shape anomaly, i.e., a desired shape is not obtained. If the charges localized near or on the surface of the semiconductor wafer or the insulating film have the same polarity as that of the charged particles, and the charged particles are irradiated toward the charge-localized surface, then the travelling course of the irradiated charged-particles is bent by Coulomb repulsion between the irradiated charged-particles and the surface localized charges. As a result, the surface of the semiconductor wafer or the insulating film is irradiated with the charged particles that circumvent the localized charges on the wafer surface, and the pattern is processed in a non-desired shape.

There is another drawback in the prior art. When, for example, forming a hole pattern or well structure in the insulating film on the semiconductor wafer, a difference in the amount of charges between the top of the holes or wells (i.e., the insulating film surface) and the bottom of the holes or wells generates a potential difference. Such a potential difference prevents positive plasma ions for promoting etching from being incident on the bottom of the holes or wells with sufficient energy. This causes an etching stop, which is a phenomenon that the etching does not proceed beyond a certain depth.

To analyze and solve such plasma-based problems including shape anomaly and etching stop, there have been proposed sensors for performing in-situ measurement of various physical quantities of the plasma itself (plasma density, plasma temperature, etc.) as well as the distribution of charges occurring on the wafer during the plasma etching processing. For example, Japanese Patent Application Publication (Kokai) No. 2007-225677 teaches such a sensor.

In Japanese Patent Application Kokai No. 2007-225677, disclosed is a charge measurement circuit for sensing a charge distribution that is arranged inside a plasma generation chamber. A voltmeter for measuring the voltage corresponding to the amount of charges is arranged outside the plasma chamber. According to this technique, the plasma chamber needs dedicated terminals through which the wires extending from the sensor are led out of the chamber and coupled to the voltmeter, in order to obtain the sensor output from inside the plasma chamber. Such wires are irradiated with the charged particles of the plasma. The output voltage is affected by a high-voltage power supply that is used for the plasma generator.

Japanese Patent Application Kokai No. 2008-170274 discloses another technique for measurement of a charge-up on a substrate. A fuse formed on the substrate is visually observed for a blowout, or the fuse resistance is measured, to measure a charge-up occurring on the substrate in the etching step. There is, however, a possibility that the fuse itself can be irradiated with plasma charged particles so that the current flowing through the fuse is significantly affected by the charged particles. When measuring deviations (localization) in the amount of charges at spatially separated locations, the increased fuse length and wiring path make the effect of the plasma charged particles ever greater. To sense deviations in the amount of charges in multi-levels, a plurality of fuses having different fusing currents need to be prepared.

An object of the present invention is to provide a substrate inter-terminal voltage sensing circuit which can promptly sense a plasma charge-up occurring on a semiconductor wafer across a wide range without connection of a voltage measuring instrument.

According to one aspect of the present invention, there is provided a voltage sensing circuit for sensing a voltage occurring between a pair of electrodes arranged on a semiconductor substrate. The voltage sensing circuit includes a resistance path that is connected between the electrodes. The voltage sensing circuit also includes a circuit power supply that is connected at one end to a midpoint of the resistance path. The voltage sensing circuit also includes at least two fuse circuits that are connected between one end of the resistance path and the other end of the circuit power supply. These fuse circuits extend in parallel with each other. The fuse circuits have different rated fusing currents from each other. Each fuse circuit includes a switch that turns ON and OFF depending on a potential difference between the one end of the resistance path and the midpoint of the resistance path. Each fuse circuit also includes a current path that is connected across the circuit power supply. The current path has a resistive element and a fuse element serially connected to the switch.

The substrate inter-terminal voltage sensing circuit is mounted on a semiconductor substrate and placed in a plasma chamber. Upon plasma processing, there may occur deviations in the amount of charges due to plasma charging. Then, different currents flow through the respective fuse circuits since the fuse circuits have different rated fusing currents from each other. The voltage between the electrodes increases with the increasing amount of charges. When the current flowing through a certain fuse circuit reaches its rated fusing current, the fuse element in that fuse circuit breaks. The relationship between the rated fusing currents at which the fuse elements break and the inter-electrode voltage (voltage between the electrodes) can be set in advance so that a difference in the amount of charges between the electrodes can be quantitatively determined by the number of fuse elements that are broken.

The resistive elements may have different resistances from each other. The fuse elements may have different rated currents from each other. The switches may be MOS transistors. The MOS transistors may have different characteristics from each other. The voltage sensing circuit may further include at least two fuse-blowout-state display units. Each display unit is associated with each fuse circuit for emitting light in a first color when the fuse element concerned is in a blowout state and for emitting light in a second color when the fuse element concerned is in no blowout state. Each display unit may be connected across the fuse element concerned. Each display unit may include two light emitting devices that in combination serve as a single combined light emitting element.

According to another aspect of the present invention, there is provided a fuse blowout state display circuitry having a plurality of display units. Each display unit includes at least one light-emitting device that is connected across each of the fuse elements of the substrate inter-terminal voltage sensing circuit of the first aspect. Each light-emitting device emits light in different colors depending on whether the fuse element concerned is in a blown state or not.

These and other objects, aspects and advantages of the present invention will become apparent to those skilled in the art from the following detailed description when read and understood in conjunction with the appended claims and drawings.

### BRIEF DESCRIPTION OF THE DRAWINGS

FIG. 1 is a schematic plan view of a substrate inter-terminal voltage sensing circuit according to a first embodiment of the present invention;

FIG. 2 shows a circuit diagram of the substrate inter-terminal voltage sensing circuit shown in FIG. 1; and

FIG. 3 illustrates a circuit diagram of a light-emitting circuit according to a second embodiment of the present invention.

### DETAILED DESCRIPTION OF THE INVENTION

### First Embodiment

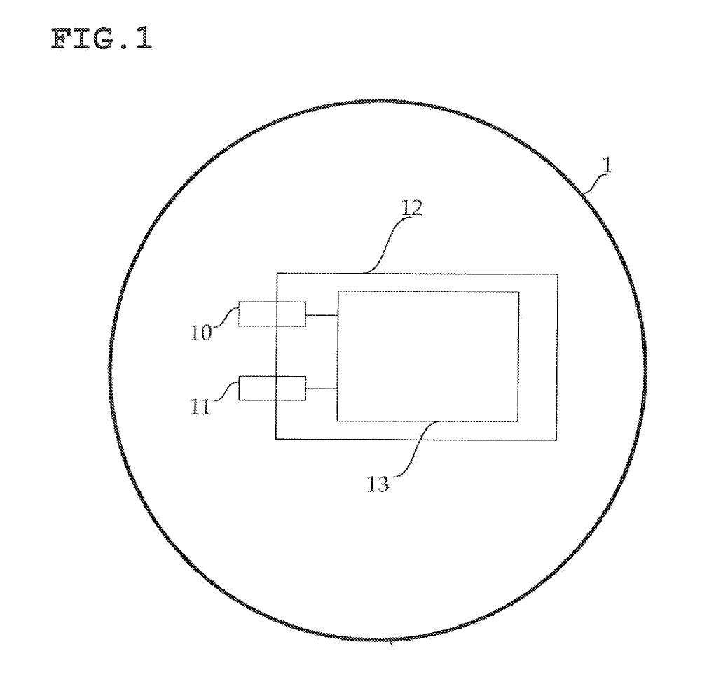

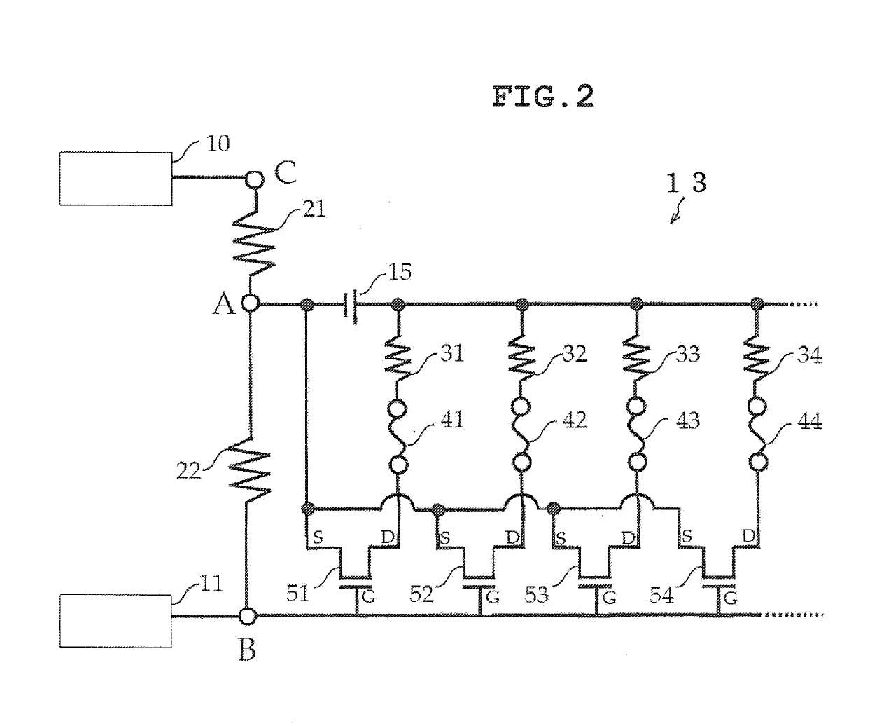

A substrate inter-terminal voltage sensing circuit according to a first embodiment of the present invention will be described with reference to FIGS. 1 and 2. The substrate inter-terminal voltage sensing circuit 13 shown in FIGS. 1 and 2 is placed in a plasma apparatus (not shown). The substrate inter-terminal voltage sensing circuit 13 of the first embodiment senses a voltage occurring between a pair of electrodes 10 and 11 arranged on a semiconductor substrate 1. The substrate inter-terminal voltage sensing circuit 13 includes a resistance path (point B to point C), a circuit power supply 15, and at least two fuse circuits (a series-connected circuit of a resistive element 31, a fuse element 41, and a MOS transistor 51, and another series-connected circuit of a resistive element 32, a fuse element 42, and a MOS transistor 52). The resistance path (point B to point C) is connected between the electrodes 10 and 11. The circuit power supply 15 is connected at its one end to a midpoint A of the resistance path (point B to point C). The fuse circuits are connected between one end (point B) of the resistance path and the other end of the circuit power supply 15. The fuse circuits extend in parallel with each other. The fuse circuits have respective different rated fusing currents in this embodiment. Each of the fuse circuits includes a switch 51, 52 that turns ON and OFF depending on a potential difference between the one end (point B) and the midpoint (point A). Each fuse circuit also includes a current path that is connected across the circuit power supply 15. This current path includes a resistive element 31, 32 and a fuse element 41, 42 serially connected to the switch 51, 52.

FIG. 1 is a schematic plan view of the substrate inter-terminal voltage sensing circuit 13 as mounted on the semiconductor substrate 1. As shown in FIG. 1, the substrate inter-terminal voltage sensing circuit 13 is connected to the electrodes 10 and 11 on the semiconductor wafer. The substrate inter-terminal voltage sensing circuit 13 is covered with a transparent insulating cover 12 for plasma protection. Through the transparent cover, it is possible to visually check whether fuse elements of the substrate inter-terminal voltage sensing circuit 13 are broken. The insulating cover 12 can also function as a protective cover that prevents the substrate inter-terminal voltage sensing circuit 13 from being directly irradiated with charged particles of plasma so that the charged particles will not flow into the fuse elements in the substrate inter-terminal voltage sensing circuit 13, wiring that connects the elements, terminals, and so on.

The circuit configuration of the substrate inter-terminal voltage sensing circuit 13 shown in FIG. 1 will be described with reference to FIG. 2. The circuit shown in FIG. 2 corresponds to the electrodes 10 and 11 and the substrate inter-terminal voltage sensing circuit 13 of FIG. 1.

The resistance path (point C to point B) composed of a series connection of a first resistor 21 and a second resistor 22 is interposed between the electrode 10 and the electrode 11. In the first embodiment, the first resistor 21 has a resistance greater than that of the second resistor 22. Specifically, the first resistor has a resistance of 900 MΩand the second resistor 100 MΩ, for example. The purpose of the configuration that the first resistor has a resistance higher than that of the second resistor is to minimize the influence of the substrate inter-terminal voltage sensing circuit 13 on the voltage occurring between the electrodes 10 and 11. Since the plasma generation chamber is subjected to high temperatures inside, the resistance path preferably has a low temperature dependency. If the resistivity varies with a change in plasma chamber temperature depending on the plasma generation condition, then the currents to flow through the fuse elements are affected accordingly.

One end of the voltage power supply 15 is connected to the point A between the first resistor 21 and the second resistor 22. In the embodiment, the power supply supplies a voltage of 3 V. Since the plasma generation chamber is subjected to high temperatures inside, it is preferred that the voltage power supply 15 has thermal resistance or is given thermal resistance treatment beforehand. If the voltage supply fails during plasma generation, the switching operations of the MOS transistors will be affected.

A series connection of the resistive element 31, fuse element 41 and MOS transistor 51 is connected in parallel to the power supply 15. Similarly, a series connection of the resistive element 32, fuse element 42 and MOS transistor 52, a series connection of a resistive element 33, a fuse element 43, and a MOS transistor 53, and a series connection of a resistive element 34, a fuse element 44, and a MOS transistor 54 are connected in parallel to the power supply 15. While there are four series connections in the illustrated embodiment (FIG. 2), the number of series connections is not limited to four but at least two. The resistive elements 31, 32, 33 and 34 have respective different resistances, such as 5Ω, 6Ω, 7Ω and 8Ω.

The fuse elements 41, 42, 43 and 44 have the same characteristics and break at a predetermined current. In the first embodiment, all the fuse elements 41 to 44 break at a current flow of 0.1 A or higher.

Each of the MOS transistors 51, 52, 53 and 54 has a drain, a gate and a source. The drain is connected to the corresponding fuse element 41, 42, 43, 44. The gate is connected to one end of the electrode 11. The source is connected to the point A. The MOS transistors 51, 52, 53 and 54 have the same characteristics, are gate-controlled by the potential at the electrode 11, and turn ON when the drain potential exceeds the source potential. It should be noted, however, that even if the drain potential exceeds the source potential, the MOS transistors turn OFF so long as the source and gate potentials are the same. Since the plasma generation chamber is subjected to high temperatures inside, it is preferred that resistive elements, fuse elements and MOS transistors have a low temperature dependency in physical properties such as resistance.

Next, the operation of the circuit 13 shown in FIGS. 1 and 2 will be described.

### 1. When the Potential Difference Between the Electrodes is 0 V

Initially, a description will be given of the case where there is no imbalance in the amount of charges between the electrodes 10 and 11 of the voltage sensing circuit 13, i.e., when there is no potential difference between the electrodes 10 and 11.

In such a case, assuming that the potential at the electrode 11 is 0 V, the MOS transistor 51 has a gate potential of 0 V and a source potential of 0 V. Since the gate-source voltage is 0 V, the MOS transistor 51 is OFF. Similarly, all other MOS transistors are OFF.

When there is no voltage between the electrodes 10 and 11, all the MOS transistors 51, 52, 53 and 54 are OFF and no current flows through the fuse elements 41, 42, 43 and 44.

2. When there is Potential Difference of 15 V Between the Electrodes

When the sensor 13 shown in FIG. 1 is exposed to plasma, charged particles of the plasma are incident on the semiconductor wafer 1 so that the wafer surface is charged. Similarly, the exposed portions of the electrodes 10 and 11 are charged. A description will be given of the case where a difference (imbalance, deviation, localization) in the amount of charges between the electrodes causes a potential difference of +15 V between the electrodes 10 and 11. For ease of description, the electrode 11 shall have a potential of +15 V and the electrode 10 a potential of 0 V.

With the potential of 0V at the electrode 10 and the potential of +15 V at the electrode 11, the voltage between the electrode 10 and the point A is 13.5 V which corresponds to 9/10 of 15 V according to the law of voltage division. The voltage between the point B and the point A is 1.5 V which corresponds to 1/10 of 15 V. Such voltage values are ascribable to the ratio of the resistor 21 and the resistor 22 of 9:1. Consequently, the potential at the point A is 13.5 V and the potential at the point B is 15 V. Setting the resistance of the resistor 21 to be higher than that of the resistor 22 can reduce the gate-source voltage of each MOS transistor 51, 52, 53, 54.

The ON and OFF states of each of the MOS transistors 51, 52, 53 and 54 will be described for the case with a potential difference of 15 V between the electrodes 10 and 11. Since the point A is connected to the sources of the respective MOS transistors 51, 52, 53 and 54, the source potentials are the same as the potential at the point A, or 13.5 V. The gates of the MOS transistors are connected to the point B, and the gate potentials are 15 V. A voltage of 1.5 V occurs between the sources and gates of the MOS transistors. The drains of the MOS transistors are connected to the point B through the power supply of 3 V, and thus have a potential higher than 13.5 V. The sources and drains of the MOS transistors receive the voltage of 3 V supplied from the voltage source minus the voltage drops across the respective resistive elements.

In such a case, the MOS transistors 51, 52, 53 and 54 individually turn ON according to the principle of the MOS transistor. A current flows through the closed loop consisting of the power supply 15→the resistor 31→the fuse element 41→the drain to source of the MOS transistor 51→the power supply 15. Currents similarly flow through the closed loops through the MOS transistors 52, 53 and 54, respectively. The MOS transistors 51, 52, 53 and 54 turn ON at the same time because the MOS transistors 51, 52, 53 and 54 have the same characteristics, have their gates connected to the same electrode 11, have their sources connected to the same point A, and have their drain potentials greater than the respective source potentials by the intervention of the power supply voltage, the resistive elements and the fuse elements.

In the embodiment shown in FIG. 2, the resistive elements 31, 32, 33 and 34 connected between the respective fuse elements 41, 42, 43 and 44 and the power supply 15 have a resistance of 5Ω, 6 Ω, 7Ω and 8Ω, respectively, increasing stepwise. The MOS transistors 51, 52, 53 and 54 have the same characteristics, and the fuse elements 41, 42, 43 and 44 have the same characteristics. The values of the currents flowing through the associated fuse elements 41, 42, 43 and 44 therefore depend on the resistances of the resistive elements 31, 32, 33 and 34, respectively.

For example, a current of 0.10 A flows through the fuse element 41, a current of 0.09 A flows through the fuse element 42, a current of 0.08 A flows through the fuse element 43, and a current of 0.07 A flows through the fuse element 44. Such current values are ascribable to the stepwise voltage drops caused by increasing the resistances of the resistive elements 31, 32, 33 and 34 connected between the respective fuse elements 41, 42, 43 and 44 and the power supply 15. As already mentioned, the resistances of the resistive elements 31, 32, 33 and 34 increase stepwise; 5Ω, 6Ω, 7Ω and 8Ω.

In practice, the voltage applied to the resistor 22 and the currents flowing through the respective fuse elements 41, 42, 43 and 44 depend on the resistances of the resistive elements 31, 32, 33 and 34 connected to the fuse elements and the characteristics of the MOS transistors 51, 52, 53 and 54. The resistances of the respective resistive elements 31, 32, 33 and 34 and the characteristics of the MOS transistors 51, 52, 53 and 54 therefore need to be adjusted (or decided) in advance so that predetermined currents flow through the respective fuse elements 41, 42, 43 and 44 when a certain voltage is applied to the resistor 22. The currents flowing through the fuse elements 41, 42, 43 and 44 thus have values that are determined by the pre-adjustment.

If, in the embodiment shown in FIG. 2, all the fuse elements 41-44 are configured to blow at a current flow of 0.1 A or higher, then only the fuse element 41 breaks since a current of 0.10 A flows through this fuse element 41. Current of 0.10 A or higher does not flow through the other fuse elements 42-44, and therefore the fuse elements 42-44 continue passing the current without breaking until uneven charges between the electrodes 10 and 11 disappear.

When a potential difference of 20 V occurs between the electrodes 10 and 11, a current of 0.11 A flows through the fuse element 41, a current of 0.10 A flows through the fuse element 42, a current of 0.09 A flows through the fuse element 43, and a current of 0.07 A flows through the fuse element 44. In such a case, assuming that all the fuse elements employed are intended to blow at a current flow of 0.1 A or higher, only the fuse elements 41 and 42 break since the currents of 0.10 A and higher flow through the fuse elements 41 and 42. The rest of the fuse elements 43 and 44 will not break since no current of 0.10 A or higher flows.

In the circuit shown in FIG. 2, only the fuse element 41 breaks when the potential difference between the electrodes 10 and 11 is 15 V. When the potential difference between the electrodes 10 and 11 increases from 15 V to 20 V, only the fuse element 42 in the subsequent stage of the fuse element 41 breaks. When the potential difference between the electrodes 10 and 11 increases further, the fuse elements 43 and 44 may break depending on the magnitude of the potential difference between the electrodes 10 and 11.

The embodiment shown in FIG. 2 has the following advantages.

The resistor 21 is connected to the electrode 10 of lower potential, the resistor 22 is connected to the electrode 11 of higher potential, and the resistance of the resistor 21 is set to be higher than that of the resistor 22. Such configuration can reduce the potential differences between the gates and sources of the MOS transistors 51, 52, 53 and 54. The ON and OFF states of the MOS transistors 51, 52, 53 and 54 are associated with the potential differences between the gates and sources of the MOS transistors as well as the drain potentials which are applied from the power supply and other components to the source potentials. This makes it possible to reduce the supply voltage of the power supply 15.

The MOS transistors 51, 52, 53 and 54 are used as switching elements. The gate insulation films of the MOS transistors prevent the currents flowing through the respective fuse elements 41, 42, 43 and 44 from flowing into the electrode 11. Since the potential difference between the electrodes 10 and 11 is not affected by the currents flowing through the respective fuse elements 41, 42, 43 and 44, it is possible to preclude unnecessary factors pertaining to the voltage sensing circuit itself and allow reliable sensing of the charging-based potential difference between the electrodes 10 and 11.

The series connections each including a resistive element, a fuse element and a MOS transistor are connected to the power supply 15 in parallel. The resistances of the resistive elements 31, 32, 33 and 34 in the respective series connections can be increased stepwise to decrease the currents to flow through the fuse elements 41, 42, 43 and 44 in the respective series connections stepwise. If the fuse elements 41, 42, 43 and 44 are intended to break at the same current value, the fuse elements break according to the potential difference between the electrodes 10 and 11. The relationship between the breaking current to flow when a fuse element breaks and the potential difference between the electrodes 10 and 11 is known in advance. The potential difference between the electrodes 10 and 11 when a fuse element breaks can thus be visually estimated without calculation. Suppose that the resistive elements connected to the fuse elements are decided so that the number of broken fuse elements increases by one for every 10 V of increase in the voltage between the electrodes 10 and 11. For example, when ten fuses are used for a voltage range of 0 V to 100 V, the number of broken fuse elements changes at intervals of 10 V. If, for example, the voltage between the electrodes 10 and 11 is 50 V, five out of the ten fuses break. If the voltage between the electrodes 10 and 11 is 100 V, all the ten fuses break. That is, in the voltage range of 0 V to 100 V, the potential difference occurring between the electrodes 10 and 11 can be known from the number of broken fuse elements with an accuracy of 10 V. With a MOS transistor, a resistive element and a fuse as a single set of series connection, the greater the number of sets arranged in the circuit for the sake of voltage measurement is, the higher the accuracy (the finer the intervals) the voltage can be known with in the voltage range of 0 V to 100 V, for example. It should be noted that the foregoing description has dealt with only a small number of elements for the sake of simplicity. It is may be desirable, however, to use 100 to 200 sets of series connections of a MOS transistor, a resistive element, and a fuse. For example, the use of 100 to 200 sets makes it possible to measure the charging-based potential difference between the electrodes 10 and 11 at intervals of 1.0 V to 0.5 V in the range of measurement voltages of 0 V to 100 V.

The relationship between the magnitude of the potential difference occurring between the electrodes 10 and 11 and the fuse elements 41 to 44 to break can be modified by adjusting the resistances of the resistive elements 31 to 34 or the characteristics of the MOS transistors 51 to 54 that are connected to the fuse elements 41 to 44. The resistances of the resistive elements 31 to 34 wired to the respective MOS transistors 51 to 54 can thus be decided to change the voltage range to measure. For example, using 100 sets of MOS transistors, resistive elements and fuse elements, it is possible to measure voltages in the range of 0 V to 1000 V at intervals of 10 V by employing the 100 different resistive elements connected to the fuse elements (100 resistors having different resistances from each other) or by employing 100 MOS transistors having different characteristics.

Each fuse element 41, 42, 43, 44 may have a width of several mm (e.g. between 5 mm to 6 mm).

According to the voltage sensing circuit 13 of the first embodiment, the detection elements such as fuses 41, 42, 43 and 44 are not directly connected to the semiconductor substrate 1, the insulating film, or the like, but through the electrodes 10 and 11. The voltage sensing circuit 13 itself is covered with the insulating plate, and therefore unnecessary factors induced by the irradiation of the fuse elements 41 to 44 with plasma-charged particles are precluded.

Since the relationship between the inter-terminal voltage and the fusing currents of the fuse elements 41 to 44 is known in advance, it is possible to measure the inter-terminal voltage by visually checking the number of blown fuse elements.

The simple circuitry in which a plurality of sets of series connections each including a MOS transistor, a resistive element, and a fuse element are connected to the power supply 15 in parallel allows in-situ measurement of the potential difference. The simple wiring of the voltage sensing circuit 13 itself prevents easy breakage and allows low cost manufacturing.

Since the sensing elements need not be connected to a voltmeter outside the plasma chamber, it is possible to measure the voltage in a wireless manner without modifications to the plasma apparatus. As compared to sensors that are connected to a voltmeter outside the plasma chamber, the sensor arrangement 13 of the invention can avoid the effect of the high-voltage power supply for plasma generation and the intrusion of plasma charged particles into the wires.

Moreover, the wireless configuration makes it possible to bring (carry) the voltage sensing circuit 13 into the plasma chamber through an ordinary transportation channel. This eliminates the need to return the plasma chamber back to the atmosphere. Contamination of the plasma chamber is thus prevented.

Modifications to the first embodiment will be described. The first embodiment has dealt with the case where the fuse circuits of the present invention are the series connections of the resistive elements 31 to 34, the fuse elements 41 to 44, and the MOS transistors 51 to 54. The description has also dealt with the case where the fuse elements 41 to 44 all have the same characteristics, the MOS transistors 51 to 54 all have the same characteristics, and only the resistive elements 31 to 34 have respective different resistances so that the fuse circuits have respective different rated fusing currents. In one modification, all the resistive elements 31 to 34 may have the same resistance and the MOS transistors 51 to 54 the same characteristics while only the fuse elements 41 to 44 have respective different fusing currents. Even with such a configuration, it is possible to give the fuse circuits respective different rated fusing currents. In another modification, the MOS transistors 51 to 54 may be configured to have respective different characteristics whereas the fuse elements 41 to 44 and resistive elements 31 to 34 may have the same characteristics, so that the fuse circuits have respective different rated fusing currents. In still another modification, all the resistive elements 31 to 34, fuse elements 41 to 44, and MOS transistors 51 to 54 may be configured to have respective different characteristics so that the fuse circuits have respective different rated currents.

### Second Embodiment

In the first embodiment shown in FIGS. 1 and 2, the voltage measurement is read (obtained) by taking the voltage sensing circuit 13 out of the plasma chamber and checking (counting) the number of broken fuse elements. If the fuse elements 41 to 44 have a size of the order of a few millimeters, it is not possible to promptly obtain the sensing result on visual inspection of the fuse elements 41 to 44. If a tester should be used to determine the breakage (disconnection) of each of the fuse elements, then prompt voltage measurement is not possible.

A second embodiment provides an additional circuit that allows easy and quick measurement of the presence or absence of a break of all the fuse elements 41 to 44 in a visually understandable display manner when the voltage sensing circuit 13 is taken out of the plasma chamber. Specifically, the sensor 13 of the first embodiment is exposed to plasma, and taken out of the plasma chamber. Then, the additional circuit of the second embodiment is connected to the sensor circuit 13 of the first embodiment. The circuit of the second embodiment includes light-emitting devices as many as corresponding to the number of fuse elements 41 to 44 of the first embodiment so that the number of broken fuse elements can be identified from the lighting of light-emitting devices that have certain emission color. This lighting circuit allows the user to visually check (count) the number of broken fuse elements easily.

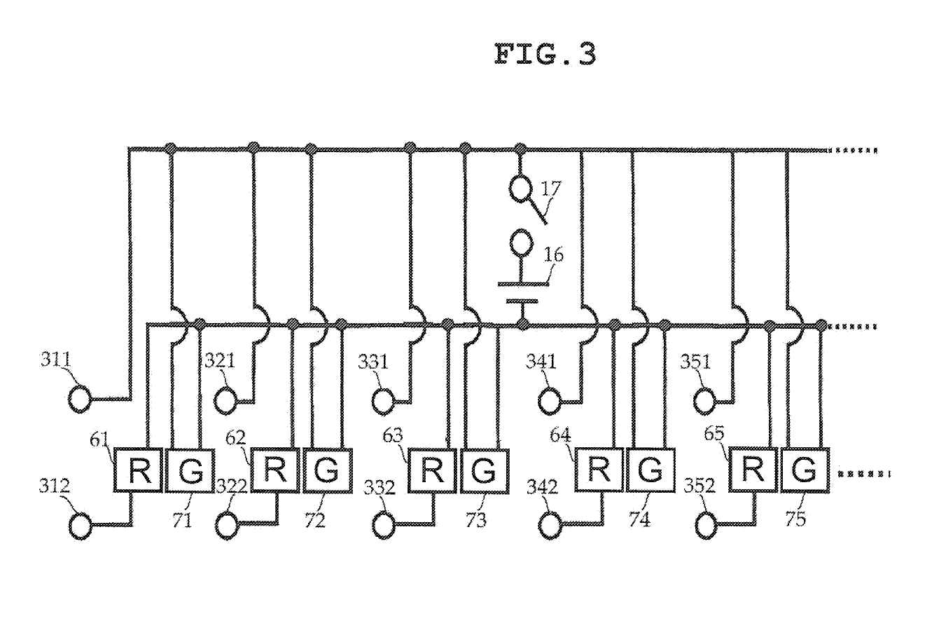

The configuration of the lighting circuit of the second embodiment will be described with reference to FIG. 3. This drawing shows a light-emitting circuit to be connected to the wireless voltage sensing circuit 13 of the first embodiment (FIG. 2).

The light-emitting circuit includes a voltage power supply 16, a switch 17, first light-emitting devices 61, 62, 63, 64 and 65, and second light-emitting devices 71, 72, 73, 74 and 75.

A pair of terminals 311 and 312 of the light-emitting circuit are connected across the fuse element 41 of the voltage sensing circuit 13 shown in FIG. 2. Terminals 321 and 322 are connected across the fuse element 42 of the voltage sensing circuit 13. Terminals 331 and 332 are connected across the fuse element 43 of the voltage sensing circuit 13. The terminals 341 and 342 are connected across the fuse element 44 of the voltage sensing circuit 13. As can be seen from FIG. 3, the pairs of terminals of the light-emitting circuit in FIG. 3 correspond to the respective fuse elements 41 to 44 of the voltage sensing circuit 13 shown in FIG. 2. The number of pairs of terminals is the same as the number of fuse elements in the voltage sensing circuit 13.

The terminals 311, 321, 331 and 341 of the light-emitting circuit are connected to the switch 17. The mating terminals 312, 322, 332 and 342 of the light-emitting circuit are connected to the negative side of the power supply 16 through the light-emitting devices 61, 62, 63 and 64, respectively. The first light-emitting devices 61, 62, 63 and 64 are red LEDs, for example. “R” in FIG. 3 represents red.

The second light-emitting devices 71, 72, 73 and 74 are arranged next to the first light-emitting devices 61, 62, 63 and 64 so as to form respective pairs. The second light-emitting devices 71, 72, 73 and 74 are connected in parallel to the series connection of the switch 17 and the power supply 16, so as to correspond to the respective pairs of terminals of the light-emitting circuit. The second light-emitting elements 71, 72, 73 and 74 are green LEDs, for example. “G” in FIG. 3 represents green. When the switch 17 is turned ON, closed loops are formed through the switch 17→the power supply 16→the respective second light-emitting devices→the switch 17, and currents flow through the respective second light-emitting devices 71 to 74 for light emission.

The operation of the light-emitting circuit shown in FIG. 3 when connected to the voltage sensing circuit 13 shown in FIG. 2 will be described.

For the sake of simplicity, the description will deal with a case where the fuse element 41 shown in FIG. 2 is broken (disconnected).

When the switch 17 is OFF, the first and second light-emitting devices have no current and thus emit no light. When the switch 17 is turned ON, the closed loops are formed and the second light emitting elements 71, 72, 73 and 74 simultaneously emit light. Since the fuse element 41 shown in FIG. 2 is broken, the terminal 312→the power supply 16→the switch 17→the terminal 311 will not form a closed loop. The first light-emitting device 61 has no current and emits no light. With the unbroken fuse element 42, a closed loop is formed through the terminal 322→the first light-emitting device 62→the power supply 16→the switch 17→the terminal 321→the fuse element 42→the terminal 322. A current flows in the first light-emitting device 62 for light emission. Similarly, the light-emitting elements 63 and 64 which are arranged so as to correspond to the unbroken fuse elements 43 and 44, respectively, constitute closed loops. Current flows in the light-emitting devices 63 and 64 for light emission.

Consequently, in the light-emitting circuit shown in FIG. 3, the first light-emitting device 61 corresponding to the broken fuse element 41 in the voltage sensing circuit 13 of FIG. 2 emits no light while the first light-emitting devices 62, 63 and 64 corresponding to the unbroken fuse elements 42, 43 and 44 and the second light-emitting devices 71, 72, 73 and 74 emit light. The first light-emitting devices 61 to 64 and the second light-emitting devices 71 to 74 are arranged to overlap each other. When a first light-emitting device emits red light, a mating (overlapped) second light-emitting device emits green light, and such a pair of light-emitting devices are regarded as a single light source, the light from this combined light source (62 and 72; 63 and 73; 64 and 74) appears yellow according to the law of three primary colors. On the other hand, a pair of first and second light-emitting devices (61, 71) that are connected for the broken fuse element (41) emit only green light and the light from the combined light source (61, 71) appears green.

In the second embodiment, one pair of light sources (i.e., first and second light-emitting devices) are assigned to each fuse element in the voltage sensing circuit 13. For a broken fuse element, only the second light-emitting device in the pair of first and second light-emitting devices emits light. The combined light source gives off the light (green) of the second light emitting device only. For an unbroken fuse element, both the first and second light-emitting devices emit light so that the combined light source gives off the composite light (yellow) of both the light-emitting devices. This makes it possible to visually check the fuse elements for a break based on the color of the light from the light-emitting devices without using a measuring instrument such as a tester and without visually finding (watching) physical disconnection of the fuse element. This is particularly advantageous if the fuse elements of FIG. 2 are large in number. In the second embodiment, the fuse elements need not be checked for physical disconnection one by one, unlike the first embodiment. It is therefore possible in the second embodiment to easily and quickly check the blowout states of all the fuse elements. This also provides a measurement result of higher reliability than when the fuse elements are visually checked for a blowout or physical disconnection.

A modification to the second embodiment will be described. A modification may be made so that only light-emitting devices that correspond to blown fuse elements in the circuit 13 emit light, blink, or decrease or increase in intensity (brightness).

This application is based on Japanese Patent Applications No. 2010-33907 filed on Feb. 18, 2010 and No. 2011-21792 filed on Feb. 3, 2011, and the entire disclosures thereof are incorporated herein by reference.

What is claimed is:

1. A voltage sensing circuit for sensing a voltage occurring between a pair of electrodes arranged on a semiconductor substrate, the voltage sensing circuit comprising:
a resistance path that is connected between the electrodes;
a circuit power supply that is connected at one end to a midpoint of the resistance path; and
at least two fuse circuits that are connected between one end of the resistance path and the other end of the circuit power supply so as to be in parallel with each other, said at least two fuse circuits having different rated fusing currents from each other, wherein each said fuse circuit includes a switch that turns on or off depending on a potential difference between said one end of the resistance path and the midpoint of the resistance path, and a current path that is connected across the circuit power supply, and said current path has a resistive element and a fuse element serially connected to the switch.

2. The voltage sensing circuit according to claim 1, wherein the resistive elements have different resistances from each other.

3. The voltage sensing circuit according to claim 1, wherein the fuse elements have different rated currents from each other.

4. The voltage sensing circuit according to claim 2, wherein the fuse elements have different rated currents from each other.

5. The voltage sensing circuit according to claim 1, wherein the switches are MOS transistors.

6. The voltage sensing circuit according to claim 5, wherein the MOS transistors have different characteristics from each other.

7. The voltage sensing circuit according to claim 1 further comprising at least two fuse blowout state display units, each said display unit being associated with each said fuse circuit for emitting light in a first color when the fuse element concerned is in a blowout state and for emitting light in a second color when the fuse element concerned is in no blowout state.

8. The voltage sensing circuit according to claim 7, wherein each said display unit is connected across the fuse element concerned.

9. The voltage sensing circuit according to claim 7, wherein each said display unit includes two light emitting devices that in combination serve as a single combined light emitting element.

10. The voltage sensing circuit according to claim 9, wherein one of the two light emitting devices is adapted to emit a red light, the other light emitting device is adapted to emit a green light, the combined light emitting element is adapted to emit a yellow light, the first color is green and the second color is yellow.

11. A fuse blowout state display circuitry comprising a plurality of display units, each said display unit including at least one light-emitting device that is connected across each of the fuse elements of the substrate inter-terminal voltage sensing circuit of claim 1, wherein each said light-emitting device emits light in different colors depending on whether the fuse element concerned is in a blown or not blown state.
